(19) United States
(12) Patent Application Publication
(10) Pub. No.: US 2024/0134407 A1
(43) Pub. Date: Apr. 25, 2024

(54) VOLTAGE SUPERVISOR

(71) Applicant: TEXAS INSTRUMENTS INCORPORATED, Dallas, TX (US)

(72) Inventors: Ramakrishna Ankamreddi, Bengaluru (IN); Rohit Phogat, Bengaluru (IN); Siddhant Rohela, Bengaluru (IN)

(21) Appl. No.: 18/403,965

(22) Filed: Jan. 4, 2024

Related U.S. Application Data
(62) Division of application No. 17/148,196, filed on Jan. 13, 2021, now Pat. No. 11,892,864.

(30) Foreign Application Priority Data
Jan. 14, 2020 (IN) 202041001565

(51) Int. Cl. G05F 3/26; G01R 19/165; G05F 3/24; G06F 1/28; H03K 17/30

(52) U.S. Cl. CPC G05F 3/262; G01R 19/16533; G01R 19/16566; G05F 3/247; G06F 1/28; H03K 17/302

(57) ABSTRACT

A voltage supervisor includes a first transistor coupled between a first supply voltage and a second supply voltage. The voltage supervisor includes a second transistor coupled between the first supply voltage and the second supply voltage. The voltage supervisor is configured to provide a first current proportional to a difference in gate-to-source voltages of the first transistor and the second transistor. The voltage supervisor is also configured to provide a second current proportional to a difference in the first supply voltage and the difference in gate-to-source voltages of the first transistor and the second transistor. The voltage supervisor is configured to compare the first current to the second current to determine a voltage value that changes a state responsive to the first supply voltage crossing a threshold.

### CROSS-REFERENCE TO RELATED APPLICATIONS

The present application is a divisional of application Ser. No. 17/148,196, filed Jan. 13, 2021, and claims priority to Indian Provisional Patent Application No. 202041001565, which was filed Jan. 14, 2020, is titled “MOSFET V_{TH} GAP BASED, TRIP-POINT SCALABLE SUPERVISOR CIRCUIT WITH QUIESCENT CURRENT REGULATION,” both of which are hereby incorporated herein by reference in their entirety.

### BACKGROUND

Voltage supervisors are useful in many applications to monitor a power supply voltage and detect certain issues with the power supply voltage. In some applications, voltage supervisors can detect if the power supply voltage falls below a threshold or rises above a threshold. Responsive to the voltage crossing a threshold, the voltage supervisor asserts a signal. That signal is useful for taking an action to ensure proper power supply operation.

### SUMMARY

In accordance with at least one example of the description, a voltage supervisor includes a first transistor coupled between a first supply voltage and a second supply voltage. The voltage supervisor includes a second transistor coupled between the first supply voltage and the second supply voltage. The voltage supervisor is configured to provide a first current proportional to a difference in gate-to-source voltages of the first transistor and the second transistor. The voltage supervisor is also configured to provide a second current proportional to a difference in the first supply voltage and the difference in gate-to-source voltages of the first transistor and the second transistor. The voltage supervisor is configured to compare the first current to the second current to determine a voltage value that changes a state responsive to the first supply voltage crossing a threshold.

In accordance with at least one example of the description, a system includes a reference current generator including a current mirror, a first transistor, a second transistor, and a first resistor, where a control terminal of the first transistor is coupled to a control terminal of the second transistor, and a first current terminal of the second transistor is coupled to the first resistor. The system includes a third transistor having a control terminal coupled to the current mirror, a first current terminal adapted to be coupled to a power supply, and a second current terminal coupled to a second resistor. The system includes a fourth transistor having a control terminal coupled to the control terminal of the third transistor, and a first current terminal adapted to be coupled to the power supply. The system includes a fifth transistor having a second current terminal coupled to the second current terminal of the fourth transistor, a control terminal coupled to the control terminal of the second transistor, and a first current terminal coupled to a sixth transistor.

In accordance with at least one example of the description, a voltage supervisor includes a reference current generator having a current minor, the current mirror configured to provide a first current that is proportional to a difference in gate-to-source voltages of a first transistor and a second transistor. The voltage supervisor includes a third transistor having a gate coupled to the current mirror, a source adapted to be coupled to a power supply, and a drain coupled to a resistor, the third transistor is configured to provide a second current proportional to a difference in a supply voltage and the difference in gate-to-source voltages of the first transistor and the second transistor. The voltage supervisor includes a fourth transistor having a gate coupled to the gate of the third transistor, a source adapted to be coupled to the power supply, and a drain having a drain voltage indicative of the supply voltage above a threshold.

### BRIEF DESCRIPTION OF THE DRAWINGS

FIG. 1 is a voltage supervisor in accordance with various examples.

FIG. 2 is a graph of temperature coefficients for strong inversion operation in accordance with various examples.

FIG. 3 is a collection of graphs that show how zero temperature coefficient is achieved in accordance with various examples.

FIG. 4 is a flowchart of a method for voltage supervision in accordance with various examples.

### DETAILED DESCRIPTION

Voltage supervisors are useful to monitor a power supply voltage and assert a signal if a threshold is reached. A node (called a trip node) has a voltage that flips from a high voltage to a low voltage or vice versa when the power supply voltage reaches a threshold. This voltage of the power supply that flips the trip node is called the trip voltage (e.g., the threshold voltage or voltage threshold). Conventional voltage supervisors have numerous disadvantages. For example, conventional voltage supervisors often have high off-stage currents, also referred to as quiescent current (I_{Q}), and have a slow response time. Also, small threshold voltages (the threshold voltages of the power supply that are being monitored) are often difficult to realize in conventional voltage supervisors. Further, achieving a programmable threshold voltage of the power supply that is being supervised is difficult in conventional voltage supervisors. For example, if the supply voltage that is being supervised is changed to a different voltage, the voltage supervisor is usually redesigned to handle the new supply voltage. Further still, conventional voltage supervisors often take up a large silicon area.

In examples herein, a voltage supervisor provides a low I_{Q}, has a quick response time, can be scaled for a range of threshold voltages, and has a small silicon area. The voltage supervisor described herein uses a circuit topology with four branches, where two different currents flow through the branches. The first current is directly proportional to a difference in gate-to-source voltages (ΔV_{GS}) of two field effect transistors (FETS). The first current is useful as a reference current, as this current does not vary with the supply voltage. The second current is directly proportional to the supply voltage, and therefore the magnitude of the second current is indicative of the magnitude of the supply voltage. These two currents are compared to determine the state of a trip node. Responsive to the supply voltage exceeding a threshold, the trip node flips from a low voltage to a high voltage because the second current overpowers the first current. Responsive to the trip node flipping, the circuit is clamped to reduce an increase in I_{Q}.

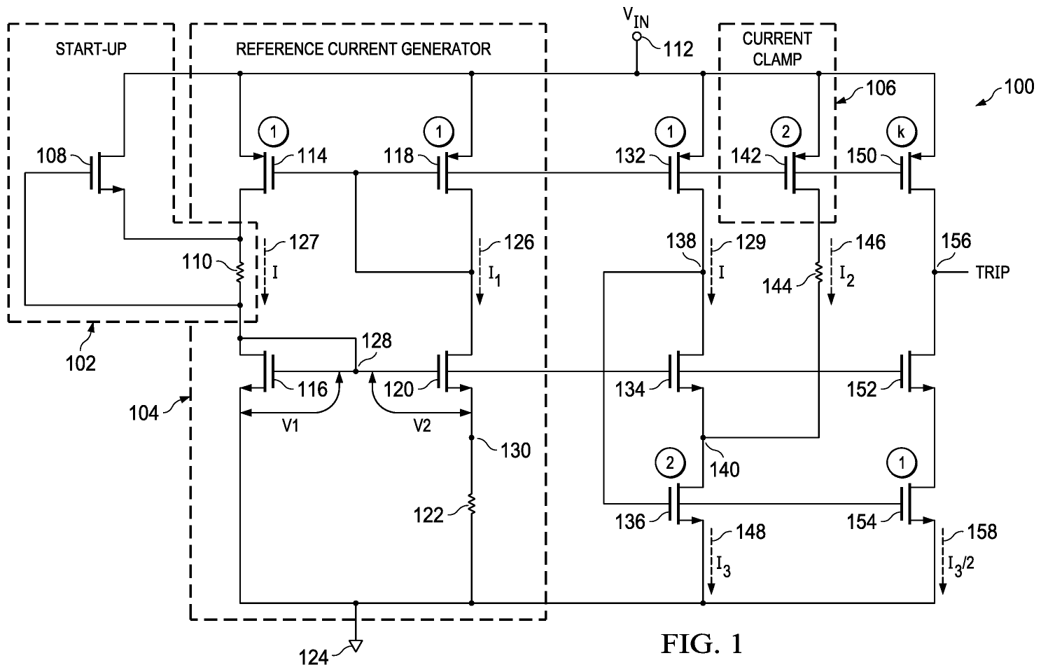

FIG. 1 is a voltage supervisor 100 in accordance with various examples herein. Voltage supervisor 100 includes a start-up section 102, a reference current generator 104, and a current clamp 106. Voltage supervisor 100 can also be described as having four vertical branches, which are described in operation below. Start-up section 102 includes transistor 108 and resistor 110. Transistor 108 is an n-type FET in one example Transistor 108 is a native transistor in one example, with a threshold voltage (V_{TH}) of approximately −100 mV. A native transistor with a different low or slightly negative V_{TH} may be used in other examples. A native transistor is a variety of FET that is intermediate between enhancement and depletion modes. In other examples, a different type of transistor may be useful. By using transistors with relatively low threshold voltages V_{TH}, voltage supervisor 100 can monitor lower supply voltage levels. If the threshold voltages V_{TH} of the transistors were relatively higher, the transistors in voltage supervisor 100 would be unable to operate at low enough voltage levels to sufficiently monitor a lower supply voltage. The source of transistor 108 is coupled to a first terminal of resistor 110 and a drain coupled to node 112. A supply voltage V_{IN} is provided at node 112 in an example A gate of transistor 108 is coupled to a second terminal of resistor 110. In examples herein, a gate of a transistor may also be referred to as a control terminal. The source or the drain of a transistor may also be referred to as current terminals. Start-up section 102 is useful for starting voltage supervisor 100 in an example. Responsive to starting voltage supervisor 100, start-up section 102 becomes inactive. The operation of start-up section 102 is described below.

Voltage supervisor 100 includes a reference current generator 104. Reference current generator 104 has two vertical branches in this example. In other examples, a different type of reference current generator is useful to provide a reference current. A first branch of reference current generator 104 includes transistor 114, resistor 110, and transistor 116. A second branch of reference current generator 104 includes transistor 118, transistor 120, and resistor 122. In an example, reference current generator operates to provide a current I₁ (described below) that is used by voltage supervisor 100 as a reference to determine if a supply voltage has exceeded a predetermined threshold.

Transistor 114 is a p-type FET in one example. In one example, transistor 114 is a low threshold voltage transistor with a threshold voltage V_{TH} of approximately 400-500 mV. In other examples, a different type of transistor may be useful. Transistor 114 has a source coupled to node 112 and a drain coupled to the first terminal of resistor 110. Transistor 114 also has a gate coupled to the gate of transistor 118. Transistor 116 is an n-type FET in one example Transistor 116 has a drain coupled to the second terminal of resistor 110. The drain of transistor 116 is also coupled to the gate of transistor 116. Transistor 116 has a source coupled to ground 124. In other examples, the rail at ground 124 could be coupled to a voltage rail other than ground 124 that is at a different voltage (a second supply voltage) than the first supply voltage V_{IN} provided at node 112.

In the second branch of reference current generator 104, transistor 118 has a source coupled to node 112 and a drain coupled to the gate of transistor 118. The drain of transistor 118 is also coupled to a drain of transistor 120. Transistor 118 is a p-type FET in one example. Transistor 120 has a gate coupled to the gate of transistor 116. Transistor 120 also has a source coupled to a first terminal of resistor 122. Transistor 120 is an n-type FET in one example. A second terminal of resistor 122 is coupled to ground 124.

In one example, transistor 118 is a low threshold voltage transistor with a threshold voltage V_{TH} of approximately 400-500 mV. In other examples, a different type of transistor may be useful. Transistors 114 and 118 have a “1” in a circle next to them. This “1” indicates that transistors 114 and 118 are similar size, and, since transistors 114 and 118 are configured as a current mirror, the current through transistor 114 will be approximately equal to the current flowing through transistor 118. Since the gates of transistors 114 and 118 are connected and the sources are connected, the gate-to-source voltages V_{GS} of transistors 114 and 118 are the same. In one example operation, current I 127 flows through transistor 114, and current I₁ 126 flows through transistor 118. Currents I₁ 126 and I 127 are approximately equal in an example Current I₁ 126 and its usage in voltage supervisor 100 is described below.

In an example, transistor 116 is a low threshold voltage transistor with a threshold voltage V_{TH} of approximately 400-500 mV. In an example, transistor 120 is a native transistor, with a threshold voltage V_{TH} of approximately −100 mV. In other examples, a different type of transistor may be useful.

Start-up section 102 operates as follows. Initially, when the supply voltage V_{IN} at node 112 is low (for example, below two volts) and the currents have not developed yet in voltage supervisor 100, node 128 is at ground (0 V). Also, the first terminal of resistor 110 is at ground, because no current I 127 is flowing through resistor 110. In turn, the V_{GS} of transistor 108 is 0 V, which is sufficient for transistor 108 to turn on and begin conducting current. The current conducted by transistor 108 acts as a start-up current and charges the parasitic capacitance at node 128, thereby increasing the voltage potential at node 128 and turning on transistor 116. Turning on transistor 116 causes other devices (transistors 114, 118, and 120) to begin conducting current in their respective current minor arrangements, and the conducted currents increase until a steady state is achieved. The positive feedback in the two leftmost branches of voltage supervisor 100 aid in reaching the steady state. Start-up section 102 ensures voltage supervisor 100 does not have zero current and remain inoperable in an example.

After current I 127 begins flowing through transistor 114, the voltage drop across resistor 110 increases, which makes the voltage at the source of transistor 108 sufficiently higher than the voltage at the gate of transistor 108 so as to turn transistor 108 off. This is because the voltage drop across resistor 110 equals the −V_{GS} of transistor 108. Resistor 110 is sized such that the voltage drop across resistor 110 is large enough to keep transistor 108 off during normal operation of voltage supervisor 100.

The first two branches in voltage supervisor 100 provide a reference current I₁ 126 that does not vary with variations in the supply voltage V_{IN}. The V_{GS} of transistor 116 is represented by V₁, which is the voltage between node 128, coupled to the gate of transistor 116, and common potential (in some examples, ground) 124. A V_{GS} of transistor 120 is represented by V₂. V₂ is the voltage between node 128 and node 130. The difference between V₁ and V₂ is equal to the voltage across resistor 122, which is also the voltage at node 130. The voltage at node 130 is therefore referred to as ΔV_{GS}, because it is the difference in the gate-to-source voltages V_{GS} of transistors 116 and 120.

Current I₁ 126 flows through transistor 120 and resistor 122 (R_{BOT}). Because the voltage across resistor 122 is known, current I₁ 126 is calculated in Equation (1):

$$\\ \begin{matrix}{I}_{1} = \frac{Δ {V}_{GS}}{{R}_{BOT}} & ( 1 )\end{matrix}$$

As seen in Equation 1, current I₁ 126 does not vary with supply voltage V_{IN}. The value of current I₁ 126 is determined by the difference between the two gate-to-source voltages V_{GS} of transistors 116 and 120, and by the value of resistor 122. As supply voltage V_{IN} varies, the difference between these two V_{GS} values remains the same. As one V_{GS} value rises, so does the other by a similar amount. As one V_{GS} value falls, so does the other by a similar amount. Current I₁ 126 is proportional to this ΔV_{GS} value, and this ΔV_{GS} value does not vary with supply voltage V_{IN}. Therefore, current I₁ 126 also does not vary with supply voltage V_{IN}. Because of this, current I₁ 126 is useful as a reference current to help determine whether supply voltage V_{IN} has risen above a threshold.

A third branch of voltage supervisor 100 includes transistors 132, 134, and 136. Transistor 132 is a p-type FET in one example. In one example, transistor 132 is a low threshold voltage transistor with a threshold voltage V_{TH} of approximately 400-500 mV. In other examples, a different type of transistor may be useful. Transistor 132 can be approximately identical to transistors 114 and 118 in an example. Transistor 132 has a “1” in a circle next to it, which indicates that transistor 132 is approximately the same size as transistors 114 and 118 and capable of conducting a similar amount of current as transistors 114 and 118 (due to transistor 132 also being part of the current mirror formed with transistors 114 and 118). Transistor 132 has a gate coupled to the gate of transistor 118 and a source coupled to node 112. A drain of transistor 132 is coupled to node 138 and a drain of transistor 134. Since transistor 132 forms part of the current mirror with transistors 114 and 118, the current I 129 that flows through transistor 132 is approximately equal to current I₁ 126 that flows through transistor 118.

Transistor 134 is an n-type (FET) native transistor in an example, with a threshold voltage V_{TH} of approximately −100 mV. In other examples, a different type of transistor may be useful. Transistor 134 has a drain coupled to the drain of transistor 132 at node 138. Transistor 134 has a gate coupled to the gate of transistor 120. Transistor 134 also has a source coupled to node 140 and to the drain of transistor 136. In an example, transistor 134 is an identical transistor to transistor 120.

Transistor 136 has a drain coupled to the source of transistor 134 and a source coupled to ground 124. Transistor 136 also has a gate coupled to node 138, which is coupled to the drain of transistor 134.

The third branch of voltage supervisor 100 includes a side branch, which has a current clamp 106 that includes a transistor 142. The side branch also includes a resistor 144. Transistor 142 has a gate coupled to the gate of transistor 132 and a source coupled to node 112. A drain of transistor 142 is coupled to a first terminal of resistor 144. A second terminal of resistor 144 is coupled to node 140.

In an example, transistor 142 is a low threshold voltage transistor with a threshold voltage V_{TH} of approximately 400-500 mV. In other examples, a different type of transistor may be useful. Transistor 142 has a “2” in a circle next to it, which indicates that transistor 142 is approximately twice the size of transistors 114, 118, and 132, and therefore capable of conducting approximately twice as much current as those three transistors. Transistor 142 also is configured to act as a current mirror with the transistors 114, 118, and 132 when the voltage at node 112 is an adequate amount above the trip point.

A current I₂ 146 flows through resistor 144. Current I₂ 146 is a current that varies with supply voltage V_{IN} at node 112 (as shown in Equation 2 below), and is useful for determining if the supply voltage V_{IN} has crossed above a threshold. In an example, V_{IN} slowly rises and approaches a threshold voltage. Current I₂ 146 flows through transistor 142. A gate-to-source voltage V_{GS} across transistor 134 is V₂, which is the voltage between nodes 128 and 130 as described above. In an example, transistors 120 and 134 are identical devices, and their gates are connected, so the gates of transistors 120 and 134 are at the same voltage. A current flowing through transistor 120 is current I₁ 126, and a current flowing through transistor 134 is current I 129, which is similar to I₁ 126 (due to the current minor). Because the current through transistors 120 and 134 is the same, and the gates of transistors 120 and 134 are at the same voltage, the sources of transistors 120 and 134 will also be at the same voltage. The voltage at the source of transistor 120 is the voltage at node 130. As described above, that voltage is ΔV_{GS}. Therefore, the voltage at node 140 is also ΔV_{GS}.

Transistor 136 is at the bottom of the third branch of voltage supervisor 100. At the drain of transistor 136 (e.g., node 140), current I 129 is combined with current I₂ 146, to create current I₃ 148 flowing through transistor 136. The current through resistor 144 is current I₂ 146, and the voltage at the second terminal of resistor 144 is ΔV_{GS}. Thus, the voltage at the first terminal of resistor 144 is useful to determine the voltage drop across resistor 144 and determine the value of current I₂ 146.

Responsive to supply voltage V_{IN} being lower than the threshold voltage that trips the trip node, the voltage at the first terminal of resistor 144 is approximately V_{IN} with a slight error. This is because transistor 142 is turned on and the voltage drop across it is negligible. Transistor 142 is approximately twice the size of transistors 114, 118, and 132, and is part of the current minor formed by these transistors. Therefore, transistor 142 has the capacity to conduct approximately twice the current I₁ 126. However, transistor 142 is sized so that the voltage difference between supply voltage V_{IN} and ground 124 is not large enough to produce that much current to flow through transistor 142. The voltage at the drain of transistor 142 is close to the voltage at the source of transistor 142 as described above, which means transistor 142 does not conduct the full amount of current it is capable of conducting. Therefore, the current I₂ 146 through transistor 142 is less than twice the current I₁ 126 in this example. Until V_{IN} reaches the voltage threshold that trips the trip node, the drain voltage of transistor 142 is close to the source voltage of transistor 142, and that source voltage is at supply voltage V_{IN}. Therefore, the voltage at the drain of transistor 142 is also close to supply voltage V_{IN}. Thus, the voltage at the first terminal of resistor 144 (R_{TOP}) is close to supply voltage V_{IN}. Equation (2) indicates the value of current I₂ 146:

$$\\ \begin{matrix}{I}_{2} = \frac{{V}_{IN} - Δ {V}_{GS}}{{R}_{TOP}} & ( 2 )\end{matrix}$$

During the operating conditions described above, where V_{IN} is below the voltage threshold that trips the trip node, current I₂ 146 varies directly with the value of supply voltage V_{IN}, instead of being twice the value of I₁ 126.

The currents flowing through each of the first three branches of voltage supervisor 100 are described above. The fourth branch of voltage supervisor 100 includes transistors 150, 152, 154 and TRIP node 156. In an example, transistor 150 is a low threshold voltage transistor with a threshold voltage V_{TH} of approximately 400-500 mV. In other examples, a different type of transistor may be useful. Transistor 150 has a “k” in a circle next to it, which indicates that transistor 150 is approximately “k” times the size of transistors 114, 118, and 132, and therefore capable of conducting approximately “k” times as much current as those transistors since it is part of the current mirror formed by those transistors. The source of transistor 150 is coupled to node 112. The gate of transistor 150 is coupled to the gate of transistor 142. The drain of transistor 150 is coupled to TRIP node 156 and to the drain of transistor 152.

Transistor 152 is an n-type (FET) native transistor in an example, with a threshold voltage V_{TH} of approximately −100 mV. In other examples, a different type of transistor may be useful. Transistor 152 has a gate coupled to the gate of transistor 134 and a source coupled to the drain of transistor 154. In an example, transistor 152 is identical to transistors 120 and 134.

Transistor 154 is a standard threshold voltage transistor with a threshold voltage V_{TH} of approximately 700 mV in an example. In other examples, a different type of transistor may be useful. Transistor 154 has a source coupled to ground 124 and a gate coupled to the gate of transistor 136. In one example, transistor 136 is also a standard voltage threshold transistor with a threshold voltage V_{TH} of approximately 700 mV. Transistor 154 has a “1” in a circle next to it, while transistor 136 has a “2” in a circle next to it. These numbers indicate that transistor 136 is approximately twice the size of transistor 154 in this example.

As described above, currents I 129 (approximately equal to I₁ 126) and I₂ 146 combine to create current I₃ 148, which is shown in Equation (3):

I₁+I₂=I₃ (3)

The current flowing through transistor 136 is current I₃ 148, and transistor 136 is twice the size of transistor 154. The gates of transistors 136 and 154 are coupled together, and the sources of transistors 136 and 154 are also coupled together at ground 124. Therefore, the gate-to-source voltages V_{GS} of transistors 136 and 154 are the same. Because transistor 136 is approximately twice the size of transistor 154, transistor 136 conducts approximately twice as much current as transistor 154. The current through transistor 136 is current I₃ 148, so the current through transistor 154 is I₃/2, shown in FIG. 1 as current 158. In an example, transistors 136 and 154 operate as a second current mirror in voltage supervisor 100, with the current being scaled responsive to the transistors 136 and 154 being different sizes.

At the top of the fourth branch, the current flowing through transistor 150 is k times the current I₁ 126 (e.g., kI₁). The current kI₁ is independent of supply voltage V_{IN}, because current I¹ 126 is independent of supply voltage V_{IN}, as described above with respect to Equation 1. Thus, the current kI₁ is approximately constant through time as supply voltage V_{IN} rises. As supply voltage V_{IN} rises, however, the current 158 (e.g., I₃/2) at the bottom of the fourth branch will also rise, because current I₃ 148 is the combination of currents I 129 (approximately equal to I₁ 126) and I₂ 146, and current I₂ 146 is dependent on V_{IN}. Responsive to current 158 rising above the current kI₁ in the fourth branch, TRIP node 156 switches state. Specifically, responsive to supply voltage V_{IN} being below the voltage threshold being monitored, the current kI₁ pulls TRIP node 156 up to a high voltage. As supply voltage V_{IN} increases enough for current 158 to rise above the current kI₁ (which is possible because current 158 varies with supply voltage V_{IN} and current kI₁ does not), TRIP node 156 is pulled to a low voltage. The voltage at TRIP node 156 that causes the node to flip is the trip voltage (e.g., the threshold voltage or voltage threshold).

The currents kI₁ and 158 can be calculated, and the trip voltage can also be calculated. The current through transistor 150, kI₁, is shown in Equation (4):

$$\\ \begin{matrix}{kI}_{1} = k \frac{Δ {V}_{GS}}{{R}_{BOT}} & ( 4 )\end{matrix}$$

The current 158 is one-half of current I₃ 148, which is calculated in Equation (5)

$$\\ \begin{matrix}{I}_{158} = \frac{1}{2} [ \frac{{V}_{IN} - Δ {V}_{GS}}{{R}_{TOP}} + \frac{Δ {V}_{GS}}{{R}_{BOT}} ] & ( 5 )\end{matrix}$$

TRIP node 156 begins to flip as the current 158 equals the current kI₁. The trip voltage is shown in Equation (6):

$$\\ \begin{matrix}{V}_{TRIP} = [ 1 + ( 2 k - 1 ) \frac{{R}_{TOP}}{{R}_{BOT}} ] Δ {V}_{GS} & ( 6 )\end{matrix}$$

Equation (6) shows that the trip voltage V_{TRIP} is directly proportional to ΔV_{GS} multiplied by a constant. The constant is a function of resistor 144 (R_{TOP}) and resistor 122 (R_{BOT}). The values of these two resistors 122 and 144 may deviate from their design values based on process variations when voltage supervisor 100 is manufactured. However, if they vary in the same manner, the process variations may cancel out according to Equation (6). The constant k is the relative device size, which is constant and will not substantially vary with process or temperature. The major variation in trip voltage V_{TRIP} is the process variation that affects ΔV_{GS}. In an example, the transistors herein can be sized so the temperature coefficient of ΔV_{GS} is approximately zero. In that case, trip voltage V_{TRIP} will also not vary noticeably with temperature.

As described above, voltage supervisor 100 is programmable for a variety of voltage thresholds. The values of resistors 122 and 144 can be adjusted to vary the trip voltage V_{TRIP}. The value of k (the relative device size) can also be adjusted to vary the trip voltage V_{TRIP}. Therefore, trip voltage V_{TRIP} can be finely tuned in examples herein. The topology of voltage supervisor 100 provides for this programmability, which means the same circuit is useful to provide a different trip voltage V_{TRIP}. Variable resistors could be used in some examples to vary the trip voltage V_{TRIP}. In other examples, resistance could be switched in or out to vary the resistance and adjust the trip voltage V_{TRIP}.

Another feature of voltage supervisor 100 in examples is that after the trip point has been reached, current I₂ 146 is limited. Current I₁ 126 is independent of supply voltage, but current I₂ 146 is not. Current clamp 106 is useful to limit current I₂ 146 as supply voltage V_{IN} rises. Current clamp 106 prevents current I₂ 146 from increasing after a certain value of supply voltage V_{IN} is reached. At that certain value of supply voltage V_{IN}, there is enough voltage margin between voltage supply V_{IN} and ground 124 for transistor 142 to supply current equal to approximately two times current I₁ 126. Transistor 142 saturates if the current flowing through it reaches two times current I₁ 126. Therefore, if supply voltage V_{IN} increases beyond that certain value, no additional current flows through that branch of voltage supervisor 100.

After the voltage supervisor 100 is fabricated, trip voltage V_{TRIP} cannot be changed unless variable resistances are used. Therefore, to prevent changes with temperature, transistors 116 and 120 should be sized so the temperature coefficient of ΔV_{GS} is approximately zero. If the temperature coefficient of ΔV_{GS} between transistors 116 and 120 is approximately zero, then the value of current I₁ 126 will also be more resistant to temperature changes, which allows for current I₁ 126 to be useful as a reference current.

Two methods are described herein to achieve a temperature coefficient near zero: one method involves using transistors in a strong inversion operation, and another method involves using transistors in a weak inversion operation. In a strong inversion operation, the V_{GS} of a transistor is significantly above the threshold voltage V_{TH}. The overdrive voltage V_{OV} is the gate-to-source voltage V_{GS} in excess of the threshold voltage V_{TH}. In a weak inversion operation (e.g., the subthreshold region), the transistor operates with a gate-to-source voltage V_{GS} below the threshold voltage V_{TH}.

First, in the example of strong inversion operation, V_{GS}=V_{TH}+V_{OV}. Also, Equation (7) shows the differences in these voltages:

ΔV_{GS}=ΔV_{TH}+ΔV_{OV} (7)

ΔV_{GS} is the difference in the gate-to-source voltages between transistors 116 and 120 as described above with respect to FIG. 1. In an example, transistor 116 is a low voltage transistor (LVT) and the variables relating to transistor 116 in the equations below will have the subscript LVT. In the example, transistor 120 is a native transistor (NAT) and the variables relating to transistor 120 in the equations below will have the subscript NAT. The variables in Equation (7) can be expanded based on the region of operation the transistor is operating in. For strong inversion operation, ΔV_{OV} equals the V_{OV} of transistor 116 minus the V_{OV} of transistor 120. Substituting these terms for ΔV_{OV} results in Equation (8):

ΔV_{GS}=ΔV_{TH}+[V_{OV(LVT)}−V_{OV(NAT)}] (8)

Current I₁ 126 in FIG. 1 is defined in Equation (9):

$$\\ \begin{matrix}{I}_{1} = \frac{k ′}{2} \frac{W}{L} {V}_{OV}^{{}^{} 2} & ( 9 )\end{matrix}$$

where k′ is the process transconductance parameter, which is a constant that depends on the process technology used to fabricate an integrated circuit; and W/L is the ratio of channel width to channel length (for transistor 120 in this example, although Equation 9 is used to find the current through other transistors as well). Solving Equation (9) for V_{OV} and substituting that solution V_{OV} for both V_{OV(LVT)} and V_{OV(NAT)} produces Equation (10):

$$\\ \begin{matrix}Δ {V}_{GS} = Δ {V}_{TH} + [ \sqrt{\frac{2 {I}_{1}}{k {{′}_{LVT} ( \frac{W}{L} )}_{LVT}}} - \sqrt{\frac{2 {I}_{1}}{k {{′}_{NAT} ( \frac{W}{L} )}_{NAT}}} ] & ( 10 )\end{matrix}$$

ΔV_{TH} is a positive value, and is equal to the threshold voltage V_{TH} of transistor 116 minus the threshold voltage V_{TH} of transistor 120. In an example, threshold voltage V_{TH} of transistor 116 is greater than zero, and threshold voltage V_{TH} of transistor 120 is approximately zero or slightly less than zero. Therefore, ΔV_{TH} is greater than zero.

Equation (11) is a rearrangement of Equation (10):

$$\\ \begin{matrix}Δ {V}_{GS} = Δ {V}_{TH} + \sqrt{\frac{2 {I}_{1}}{W / L}} [ \frac{1}{\sqrt{k {′}_{LVT}}} - \frac{1}{\sqrt{k {′}_{NAT}}} ] & ( 11 )\end{matrix}$$

In this example, the LVT and NAT transistors are identically sized, so the W/L variable is the same for each transistor and can be moved outside of the bracket as shown in Equation (11). The next step is to identify the temperature coefficient of ΔV_{TH} and the temperature coefficient of the term that is added to ΔV_{TH} in Equation (11). To achieve a zero temperature coefficient, the temperature coefficient of ΔV_{TH} should be canceled by the temperature coefficient of the other term in Equation (11) (which is equivalent to ΔV_{OV}, as shown in Equation (7)).

ΔV_{TH} is process dependent, so it cannot be adjusted to achieve a zero temperature coefficient. For the ΔV_{OV} term, the size of the transistors can be modified (by modifying the W and L terms). The W and L variables can be adjusted to vary the temperature coefficient of the ΔV_{OV} term in the appropriate direction so as to cancel the temperature coefficient of ΔV_{TH}. For example, if the temperature coefficient of ΔV_{TH} is Θ, the other term should be −Θ so the terms cancel. Also, k′ is equal to the mobility (μ) of a device times the oxide capacitance C_{OX} (k′=μC_{OX} ).

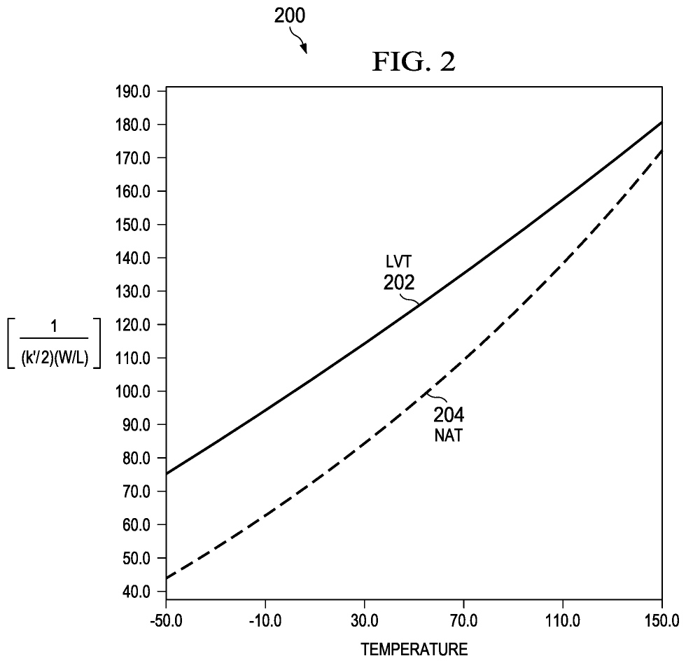

FIG. 2 is a graph 200 of temperature coefficients for strong inversion operation according to an example. Graph 200 graphs the reciprocal of (k′/2)(W/L) versus temperature. The reciprocal of (k′/2)(W/L) is graphed on the y-axis. The x-axis is temperature, in Celsius. Curve 202 is the reciprocal of (k′/2)(W/L) for an LVT device such as transistor 116. Curve 204 is the reciprocal of the term (k′/2)(W/L) for a NAT device such as transistor 120. As seen in graph 200, the reciprocal of this term for LVT (curve 202) has a lower slope than the reciprocal of this term for NAT (curve 204). If these two terms are subtracted (which is done in the last part of Equation (11)), the result is a negative temperature coefficient. Therefore, the second term on the right side of Equation (11),

$$\\ \sqrt{\frac{2 {I}_{1}}{W / L}} [ \frac{1}{\sqrt{k {′}_{LVT}}} - \frac{1}{\sqrt{k {′}_{NAT}}} ]$$

(the radical multiplied by the term in the brackets), which is added to ΔV_{TH}, falls with rising temperature. This means the second term as shown above has a negative temperature coefficient. That second term can be adjusted by altering the W and L values (of the identically sized LVT and NAT transistors) until its absolute value equals the absolute value of ΔV_{TH}. If those absolute values are equal, the second term cancels ΔV_{TH} and the resulting temperature coefficient is approximately zero.

For the second case of subthreshold or weak inversion operation, ΔV_{GS}=ΔV_{TH}+ΔV_{OV}. Similar mathematical substitutions as described above are performed for this type of operation. However, for subthreshold operation the ΔV_{OV} term is different than for the strong inversion operation. In an example, subthreshold operation is characterized by Equation (12):

$$\\ \begin{matrix}Δ {V}_{GS} = Δ {V}_{TH} + {nV}_{T} ln ( \frac{k {′}_{NAT}}{k {′}_{LVT}} \frac{{( \frac{W}{L} )}_{NAT}}{{( \frac{W}{L} )}_{LVT}} ) & ( 12 )\end{matrix}$$

The logarithmic term in Equation (12) (which is equivalent to ΔV_{OV}) is adjusted, like with the strong inversion operation above, in order to cancel out the temperature coefficient term of ΔV_{TH}. The logarithmic term can be adjusted by adjusting the W and L variables for either or both of the LVT and NAT transistors.

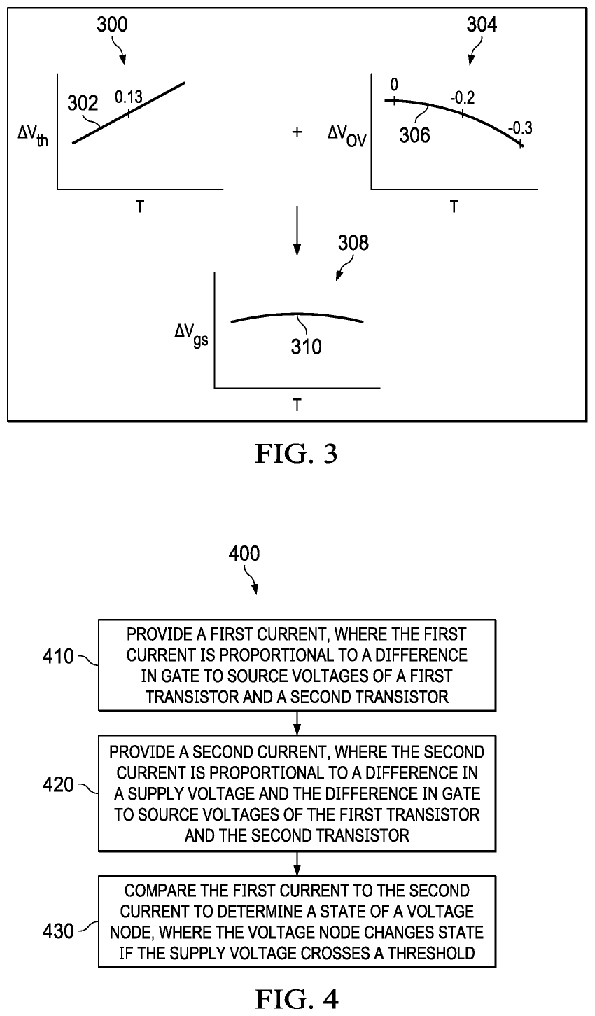

FIG. 3 is a collection of graphs that shows the cancellation of the temperature coefficients in the subthreshold operation. Graph 300 is a graph of ΔV_{TH} (in Volts) versus temperature (in Celsius). The temperature coefficient is shown as curve 302. Curve 302 has a positive slope of approximately 0.13 as indicated in graph 300.

Graph 304 is a graph of ΔV_{OV} with respect to temperature. The temperature coefficient is shown as curve 306. Curve 306 has a negative slope, with a slope of approximately zero on the left edge of curve 306, a slope of approximately −0.2 in the middle of curve 306, and a slope of approximately −0.3 on the right edge of curve 306.

In an example, if the slope of ΔV_{OV} is made as equally negative as the ΔV_{TH} slope is positive, the result is an umbrella-shaped curve like curve 310 shown in the graph 308. Graph 308 is the graph of ΔV_{GS} with respect to temperature, and is a result of combining curves 302 and 306. On curve 310, the initial (far left) and final (far right) points are at a similar V_{GS} value. Therefore, with an increase in temperature, curve 310 does not exhibit a gradient increase or a gradient decrease; instead, the result is the umbrella-shaped curve. Curve 310 is not perfectly horizontal, so there is some effect caused by a change in temperature, but it is close to horizontal, so the effect is small in some examples.

FIG. 4 is a flowchart of a method 400 for voltage supervision in accordance with various examples herein. Although the method 400 is described in conjunction with FIGS. 1-3, any system configured to perform the method, in any suitable order, falls within the scope of this description. In one example, the components in FIG. 1 perform the method 400.

Method 400 begins at step 410, where the voltage supervisor 100 provides a first current, where the first current is proportional to a difference in gate-to-source voltages V_{GS} of a first transistor and a second transistor. In an example, the current minor of transistors 114 and 118 provide the first current I₁ 126. The first current I₁ 126 is proportional to the difference in the V_{GS} of transistors 116 and 120. Transistor 116 is the first transistor and transistor 120 is the second transistor in an example.

Method 400 continues at step 420, where the voltage supervisor 100 provides a second current, where the second current is proportional to a difference in a supply voltage and the difference in gate-to-source voltages V_{GS} of the first transistor and the second transistor. In an example, the second current is current I₂ 146 as described above in Equation (2). Equation (2) shows that current I₂ 146 is proportional to V_{IN}−ΔV_{GS}. In one example, transistors 116 and 120 are first and second transistors, respectively, while transistor 142 is a third transistor that provides the second current.

Method 400 continues at step 430, where the voltage supervisor 100 compares the first current to the second current to determine a state of a voltage node, where the voltage node changes state if the supply voltage crosses a threshold. As described above with respect to FIG. 1, if the current 158 rises above the current kI₁ due to an increase in supply voltage V_{IN}, the TRIP node 156 changes state. In one example, transistor 150 is a fourth transistor and transistor 152 is a fifth transistor that conduct the current kI₁. Transistor 154 is a sixth transistor that conducts the current 158, as part of a second current mirror with transistor 136. In other examples, any suitable method is useful for comparing the first current to the second current.

Examples described herein can be used in a vast number of applications. Any end equipment system that benefits from accurate voltage supervision circuitry can benefit from the examples herein, due to the scalable and compact design of voltage supervisor 100. Voltage supervisor 100 functions independently of the region of operation of the transistors. That is, in one example, voltage supervisor 100 can use reduced area by using transistors in strong inversion. In another example, transistors are useful in subthreshold operation for low I_{Q} operation.

In voltage supervisor 100, the constant that determines the directly proportional relationship between the trip point and ΔV_{GS} is scalable as well as process independent. The constant can be scaled in two ways (current minor ratio and resistor ratio). Scaling in two ways allows the trip point to be programmed in a fine manner, without a large increase in silicon area.

In voltage supervisor 100, I_{Q} for the described topology is independent of increasing V_{IN} after the trip point has been reached. This independence is achieved by use of current clamp 106 in the branch of voltage supervisor 100 that carries the current I₂ 146, which is dependent on V_{IN}.

In some examples, voltage supervisor 100 works with a range of approximately 1.0 volts to approximately 5.0 volts. Also, voltage supervisor 100 is self-starting due to start-up section 102. Response time is fast for voltage supervisor 100 compared to conventional systems.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead. For example, a p-type metal-oxide-silicon FET (“MOSFET”) may be used in place of an n-type MOSFET with little or no changes to the circuit. Furthermore, other types of transistors may be used (such as bipolar junction transistors (BJTs)).

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value. Modifications are possible in the described examples, and other examples are possible within the scope of the claims.

What is claimed is:

1. A system comprising:
a first transistor having a control terminal, a first current terminal, and a second current terminal;
a second transistor having a control terminal coupled to the control terminal of the first transistor, a first current terminal coupled to the control terminal of the second transistor, and a second current terminal;
a first resistor having a first terminal coupled to the first current terminal of the first transistor;
a third transistor having a control terminal, a first current terminal coupled to a second terminal of the first resistor and the control terminal of the third transistor, and a second current terminal;
a fourth transistor having a control terminal coupled to the control terminal of the third transistor, a first current terminal coupled to the first current terminal of the second transistor, and a second current terminal;
a second resistor having a first terminal coupled to the second current terminal of the fourth transistor;
a fifth transistor having a control terminal coupled to the control terminal of the second transistor;
a sixth transistor having a control terminal coupled to the control terminal of the fourth transistor, a first current terminal coupled to the first current terminal of the fifth transistor;
a seventh transistor having a control terminal coupled to the first current terminal of the sixth transistor;
an eighth transistor having a control terminal coupled to the control terminal of the fifth transistor, a first current terminal, and a second current terminal coupled to the second current terminal of the fifth transistor; and
a third resistor having a first terminal coupled to the first current terminal of the eighth transistor, and a second terminal coupled to the second current terminal of the sixth transistor.

2. The system of claim 1, further comprising:
a ninth transistor having a control terminal coupled to the control terminal of the eighth transistor, a first current terminal, and a second current terminal coupled to the second current terminal of the eighth transistor.

3. The system of claim 2, further comprising:
a tenth transistor having a control terminal coupled to the control terminal of the sixth transistor, a first current terminal coupled to the first current terminal of the ninth transistor, and a second current terminal.

4. The system of claim 3, further comprising:
an eleventh transistor having a control terminal coupled to the control terminal of the seventh transistor, a first current terminal coupled to the second current terminal of the second current terminal of the tenth transistor, and a second current terminal coupled to the second current terminal of the seventh transistor.

5. The system of claim 4, further comprising:
a twelfth transistor having a control terminal coupled to the second terminal of the first resistor, a first current terminal coupled to the second current terminal of the first transistor, and a second current terminal coupled to the first terminal of the first resistor.

6. The system of claim 5, wherein:
the second current terminal of the first transistor is coupled to the second current terminal of the second transistor.

7. The system of claim 6, wherein:
a first current between the first current terminal of the second transistor and the first current terminal of the fourth transistor is proportional to a difference in gate-to-source voltages of the third transistor and the fourth transistor.

8. The system of claim 7, wherein:
a second current through the third resistor is proportional to a difference in a supply voltage and the difference in gate-to-source voltages of the third transistor and the fourth transistor.

9. The system of claim 8, wherein:
the eighth transistor is configured to clamp the second current in response to the supply voltage crossing a threshold.

10. The system of claim 9, wherein:
the threshold is based at least in part on a value of the second resistor and a value of the third resistor.

11. A system, comprising:
a reference current generator including a current minor, a first transistor, a second transistor, and a first resistor, where a control terminal of the first transistor is coupled to a control terminal of the second transistor, and a first current terminal of the second transistor is coupled to the first resistor;
a third transistor having a control terminal coupled to the current minor, a first current terminal adapted to be coupled to a power supply, and a second current terminal coupled to a second resistor;
a fourth transistor having a control terminal coupled to the control terminal of the third transistor, and a first current terminal adapted to be coupled to the power supply; and
a fifth transistor having a second current terminal coupled to the second current terminal of the fourth transistor, a control terminal coupled to the control terminal of the second transistor, and a first current terminal coupled to a sixth transistor.

12. The system of claim 11, wherein the current mirror is a first current minor, and the system further comprises a second current mirror coupled to the first current terminal of the fifth transistor.

13. The system of claim 11, wherein a threshold voltage of the first transistor is greater than a threshold voltage of the second transistor.

14. The system of claim 11, wherein the first transistor is an n-channel transistor with a threshold voltage below approximately 500 millivolts.

15. The system of claim 11, wherein the second transistor is an n-channel native transistor.

16. The system of claim 11, wherein a second current terminal of the first transistor is coupled to the current minor, and a second current terminal of the second transistor is coupled to the current mirror.

17. A voltage supervisor, comprising:
a reference current generator including:
a first branch including a first transistor, a first resistor, and a second transistor; and
a second branch including a third transistor, a fourth transistor, and a second resistor;
a third branch including a fifth transistor, a sixth transistor, and a seventh transistor;
a fourth branch including an eighth transistor, a ninth transistor, and a tenth transistor; and
a clamp

18. The voltage supervisor of claim 17, wherein:
the clamp is configured to limit a current responsive to a supply voltage crossing a threshold.

19. The voltage supervisor of claim 18, wherein:
the first branch, the second branch, the third branch, and the fourth branch are in parallel.

20. The voltage supervisor of claim 17, wherein:
the second transistor and the fourth transistor are sized to reduce a temperature coefficient of a difference in gate-to-source voltages of the first transistor and the second transistor.
